(19) United States
(12) Patent Application Publication
(10) Pub. No.: US 2024/0290799 A1
(43) Pub. Date: Aug. 29, 2024

(54) DISPLAY DEVICE

(71) Applicant: LG Display Co., Ltd., Seoul (KR)

(72) Inventors: Sangmin PARK, Gimpo-si (KR); JinYeong KIM, Goyang-si (KR); Youngchor CHO, Paju-si (KR); SeongHwan JU, Paju-si (KR)

(73) Assignee: LG Display Co., Ltd., Seoul (KR)

(21) Appl. No.: 18/589,091

(22) Filed: Feb. 27, 2024

(30) Foreign Application Priority Data
Feb. 28, 2023 (KR) 10-2023-0026815

(51) Int. Cl. H01L 27/12; H01L 25/16; H01L 33/60

(52) U.S. Cl. CPC H01L 27/1248; H01L 25/167; H01L 33/60

(57) ABSTRACT

A display device in one example includes a substrate including an active area and a non-active area adjacent to the active area, a plurality of sub pixels disposed in the active area and each including a plurality of transistors, a first passivation layer covering the plurality of transistors, a planarization layer covering the first passivation layer, a second passivation layer covering the planarization layer, an adhesive layer disposed on the second passivation layer, and a plurality of light emitting diodes disposed on the adhesive layer. The first passivation layer and the second passivation contact with each other in the non-active area, so as to seal an end portion of the planarization layer.

### CROSS-REFERENCE TO RELATED APPLICATIONS

This application claims priority to Korean Patent Application No. 10-2023-0026815, filed in the Republic of Korea on Feb. 28, 2023, the entire contents of which is hereby expressly incorporated by reference into the present application.

### BACKGROUND

### Field

The present disclosure relates to a display device, and more particularly, to a display device using a light emitting diode (LED).

### Discussion of the Related Art

In the current information society, display devices play a vital role in promoting communication and sharing information in an effective manner. The display device can be applied in a wide array of electronic devices such as in a monitor of a computer, a television, a cellular phone, or the like.

Among the display device, there are an organic light emitting display (OLED) device which is a self-emitting device, a liquid crystal display (LCD) device which requires a separate light source, and the like.

Further, an applicable range of the display device is diversified to personal digital assistants as well as monitors of computers and televisions. As such, a display device with a large display area and a reduced volume and weight is being focused and studied.

Furthermore, a display device including a light emitting diode (LED) is attracting attention as a next generation display device. Since the LED is formed of an inorganic material, rather than an organic material, reliability is excellent so that a lifespan thereof is longer than the liquid crystal display device or the organic light emitting display device.

In addition, the LED has a fast lighting speed, excellent luminous efficiency, and a strong impact resistance so that a stability of the display device using the LEDs is excellent and an image having a high luminance can be displayed by such display device.

On the other hand, the display device using the LEDs can face a limitation such as moisture permeation or electrical shorts, which needs to be addressed.

### SUMMARY OF THE DISCLOSURE

Accordingly, an object to be achieved by the present disclosure is to provide a display device which is capable of minimizing moisture permeation from an organic layer.

Another object to be achieved by the present disclosure is to provide a display device which minimizes a short defect of a reflection plate and conductive components disposed to be adjacent to the reflection plate.

Another object to be achieved by the present disclosure is to provide an improved display device, which addresses the limitations and problems associated with the related art.

Objects of the present disclosure are not limited to the above-mentioned objects, and other objects, which are not mentioned above, can be clearly understood by those skilled in the art from the following descriptions.

According to an aspect of the present disclosure, a display device includes a substrate including an active area in which the plurality of sub pixels are disposed and a non-active area which encloses the active area; a plurality of transistors disposed in each of the plurality of sub pixels; a first passivation layer which covers the plurality of transistors and is formed of an inorganic material; a first planarization layer which covers the first passivation layer; a second passivation layer which covers the first planarization layer and is formed of an inorganic material; an adhesive layer disposed on the second passivation layer; a plurality of light emitting diodes disposed on the adhesive layer; and a plurality of pad electrodes which are disposed in the non-active area on a top and a bottom of the substrate to transmit a signal to the plurality of sub pixels, where an end of the first passivation layer is covered by the first planarization layer in an area overlapping the plurality of pad electrodes, and an end of the second passivation layer is covered by the adhesive layer in the area overlapping the plurality of pad electrodes.

Other detailed matters of the embodiments of the present disclosure are included in the detailed description and the drawings.

According to the effects and advantages of the present disclosure, the moisture permeation from the organic layer is minimized, reduced or eliminated to improve the reliability of the display device.

According to the effects and advantages of the present disclosure, a short defect of a reflection plate and conductive components disposed to be adjacent to the reflection plate is minimized, reduced or eliminated to improve the reliability of the display device.

The effects and advantages according to the present disclosure are not limited to the contents exemplified above, and more various effects and advantages are included in the present specification.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an embodiment of the present disclosure;

FIG. 2A is a partial cross-sectional view of a display device according to an embodiment of the present disclosure;

FIG. 2B is a perspective view of a tiling display device according to an embodiment of the present disclosure;

FIG. 3A is a plan view of a display panel before grinding of a display device according to an embodiment of the present disclosure;

FIG. 3B is a plan view of the display panel of FIG. 3A after the grinding of the display device according to an embodiment of the present disclosure;

FIGS. 4A and 4B are plan views illustrating a pixel area of a display device according to an embodiment of the present disclosure;

FIG. 5 is a cross-sectional view of a pixel area of a display device according to an embodiment of the present disclosure;

FIG. 6 is a cross-sectional view taken along line A-A′ of FIG. 3B;

FIG. 7 is a cross-sectional view taken along line B-B′ of FIG. 3B;

FIG. 8 is a cross-sectional view taken along line C-C′ of FIG. 3B; and

FIG. 9 is a cross-sectional view taken along line D-D′ of FIG. 3B.

### DETAILED DESCRIPTION OF THE EMBODIMENTS

Advantages and characteristics of the present disclosure and method(s) of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The term “exemplary” or “exemplarily” is used to mean an example, and is interchangeably used with the term “example”. Further, embodiments are example embodiments and aspects are example aspects. Any implementation described herein as an “exemplary”, “exemplarily” or “example” is not necessarily to be construed as preferred or advantageous over other implementations. Also, an “embodiment” is an “embodiment” of the present disclosure or invention, and can be interchangeably used with an “aspect”.

The shapes, sizes, ratios, angles, numbers, and the like illustrated in the accompanying drawings for describing the exemplary embodiments of the present disclosure are merely examples, and the present disclosure is not limited thereto. Further, in the following description of the present disclosure, a detailed explanation of known related technologies can be omitted to avoid unnecessarily obscuring the subject matter of the present disclosure. The terms such as ‘including’, ‘having’, ‘consist of,’ etc. used herein are generally intended to allow other components to be added unless the terms are used with the term ‘only’. Any references to singular can include plural unless expressly stated otherwise.

Components are interpreted to include an ordinary error range even if not expressly stated.

When the position relation between two parts is described using the terms such as ‘on’, ‘above’, ‘below’, ‘under’, ‘next’, one or more parts can be positioned between the two parts unless the terms are used with the term ‘immediately’ or ‘directly’.

When an element or layer is disposed “on” another element or layer, at least another layer or another element can be interposed directly on the other element or therebetween.

Although the terms “first”, “second”, and the like are used for describing various components, these components are not confined by these terms. These terms are merely used for distinguishing one component from the other components, and may not define order or sequence. Therefore, a first component to be mentioned below can be a second component in a technical concept of the present disclosure.

Like reference numerals generally denote like elements throughout the specification.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, various embodiments of the present disclosure will be described in detail with reference to accompanying drawings. All the components of each display device according to all embodiments of the present disclosure are operatively coupled and configured.

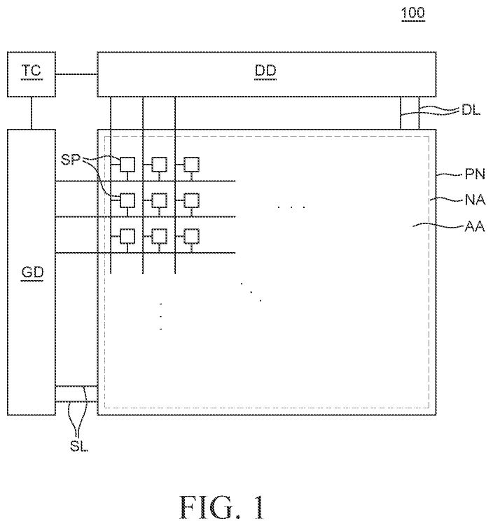

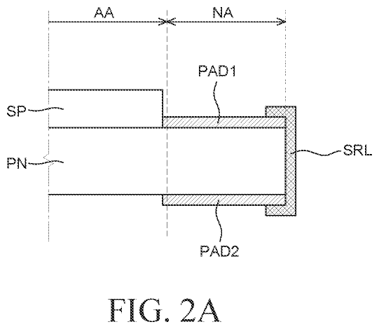

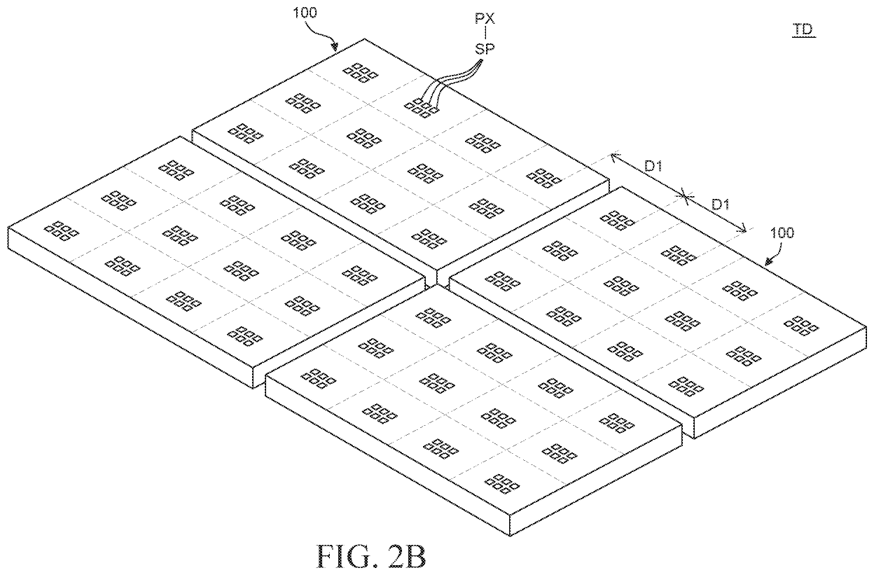

FIG. 1 is a schematic diagram of a display device according to an exemplary embodiment of the present disclosure. FIG. 2A is a partial cross-sectional view of a display device according to an exemplary embodiment of the present disclosure. FIG. 2B is a perspective view of a tiling display device according to an exemplary embodiment of the present disclosure. In FIG. 1, for the convenience of description, among various components of a display device 100, a display panel PN, a gate driver GD, a data driver DD, and a timing controller TC are illustrated.

Referring to FIG. 1, the display device 100 includes the display panel PN including a plurality of sub pixels SP, the gate driver GD and the data driver DD which supply various signals to the display panel PN, and the timing controller TC which controls the gate driver GD and the data driver DD.

The gate driver GD supplies a plurality of scan signals to a plurality of scan lines SL in accordance with a plurality of gate control signals supplied from the timing controller TC. In an example, one gate driver GD is disposed to be spaced apart from one side of the display panel PN. However, the number of the gate drivers GD and the placement thereof are not limited thereto and other variations are possible and part of the present disclosure.

The data driver DD converts image data input from the timing controller TC into a data voltage using a reference gamma voltage in accordance with a plurality of data control signals supplied from the timing controller TC. The data driver DD can supply the converted data voltage to the plurality of data lines DL.

The timing controller TC aligns image data input from the outside to supply the image data to the data driver DD. The timing controller TC can generate a gate control signal and a data control signal using synchronization signals input from the outside, such as a dot clock signal, a data enable signal, and horizontal/vertical synchronization signals. The timing controller TC supplies the generated gate control signal and the data control signal to the gate driver GD and the data driver DD, respectively, to control the gate driver GD and the data driver DD.

The display panel PN displays images to a user and includes the plurality of sub pixels SP arranged in a matrix configuration. In the display panel PN, the plurality of scan lines SL and the plurality of data lines DL intersect each other and the plurality of sub pixels SP are connected to the scan lines SL and the data lines DL, respectively. In addition, each of the plurality of sub pixels SP can be connected to a high potential power line, a low potential power line, a reference line, and the like.

In the display panel PN, an active area AA and a non-active area NA enclosing the active area AA can be defined. The non-active area NA can surround the active area AA entirely or only in part.

The active area AA is an area in which images are displayed in the display device 100, and can be referred to as a display area. In the active area AA, the plurality of sub pixels SP forming a plurality of pixels PX and a circuit for driving the plurality of sub pixels SP can be disposed on a substrate. The plurality of sub pixels SP cab be a minimum unit which configures the active area AA and n sub pixels SP can form one pixel.

In each of the plurality of sub pixels SP, a light emitting diode (or light emitting element), a thin film transistor for driving the light emitting diode, and the like can be disposed. The plurality of light emitting diodes can be defined in different manners depending on the type of the display panel PN. For example, when the display panel PN is an inorganic light emitting display panel, the light emitting diode can be a light emitting diode (LED) or a micro light emitting diode (LED).

In the active area AA, a plurality of wiring lines or other signal lines which transmit various signals to the plurality of sub pixels SP are disposed. For example, the plurality of wiring lines can include a plurality of data lines DL which supply a data voltage to each of the plurality of sub pixels SP, a plurality of scan lines SL which supply a scan signal to each of the plurality of sub pixels SP, and the like. The plurality of scan lines SL extend in one direction in the active area AA to be connected to the plurality of sub pixels SP, and the plurality of data lines DL extend in a direction different from the one direction in the active area AA to be connected to the plurality of sub pixels SP. In addition, in the active area AA, a low potential power line, a high potential power line, and the like can be further disposed, but are not limited thereto.

The non-active area NA is an area where images are not displayed so that the non-active area NA can be defined as an area extending from the active area AA. The non-active area NA can be referred to as a non-display area, which can include a bezel area. In the non-active area NA, a link line which transmits a signal to the sub pixel SP of the active area AA, a pad electrode, a driving integrated circuit (IC), such as a gate driver IC or a data driver IC, or the like, can be disposed.

In the meantime, the non-active area NA can be located on a rear surface of the display panel PN, for example, on a surface on which the sub pixels SP are not disposed or can be omitted, and is not limited the configurations illustrated in the drawings.

In the meantime, a driver, such as the gate driver GD, the data driver DD, and the timing controller TC, can be connected to the display panel PN in various ways. For example, the gate driver GD can be mounted in the non-active area NA in a gate in panel (GIP) manner or mounted between the plurality of sub pixels SP in the active area AA in a gate in active area (GIA) manner. For example, the data driver DD and the timing controller TC can be formed in a separate flexible film and a printed circuit board. The data driver and the timing controller can be electrically connected to the display panel PN by bonding the flexible film and the printed circuit board to the pad electrode formed in the non-active area NA of the display panel PN.

However, if the gate driver GD is mounted in the GIP manner and the data driver DD and the timing controller TC transmit a signal to the display panel PN through a pad electrode of the non-active area NA, an area of the non-active area NA for disposing the gate driver GD and the pad electrode is needed and can be larger than a predetermined level. Accordingly, a bezel area for the display device can be increased.

In contrast, in the example of FIG. 1, the gate driver GD is mounted in the active area AA in the GIA manner and a side line (e.g., SRL in FIG. 2A) which connects the signal line on the front surface of the display panel PN to the pad electrode on a rear surface of the display panel PN is formed to bond the flexible film and the printed circuit board onto a rear surface of the display panel PN. As a result, the non-active area NA can be reduced and minimized on the front surface of the display panel PN. That is, since the gate driver GD, the data driver DD, and the timing controller TC are connected to the display panel PN as described above, a zero bezel with substantially no bezel can be implemented in the display device according to the present disclosure.

Specifically, referring to the examples of FIGS. 2A and 2B, in the non-active area NA of the display panel PN, a plurality of pad electrodes PAD1 and PAD2 for transmitting various signals to the plurality of sub pixels SP are disposed. For example, in the non-active area NA on the front surface of the display panel PN, a plurality of first pad electrodes PAD1 which transmit a signal to the plurality of sub pixels SP are disposed. In the non-active area NA on the rear surface of the display panel PN, a plurality of second pad electrodes PAD2 which are electrically connected to a driving component, such as a flexible film and the printed circuit board, are disposed. For example, on the front surface of the display panel PN on which images are displayed, only a pad area of the non-active area NA in which the first pad electrode PAD1 is disposed can be formed at minimum.

In this case, various signal lines connected to the plurality of sub pixels SP, for example, a scan line SL, a data line DL, or the like extend from the active area AA to the non-active area NA to be electrically connected to the first pad electrode PAD1.

Further, a side line SRL is disposed along a side surface of the display panel PN. The side line SRL can electrically connect the first pad electrode PAD1 on the front surface of the display panel PN and the second pad electrode PAD2 on the rear surface of the display panel PN to each other. Therefore, a signal from a driving component on the rear surface of the display panel PN can be transmitted to the plurality of sub pixels SP through the second pad electrode PAD2, the side line SRL, and the first pad electrode PAD1. Accordingly, a signal transmitting path from the front surface of the display panel PN to the side surface and the rear surface can be formed to minimize the size of the non-active area NA on the front surface of the display panel PN.

Referring to another example shown in FIG. 2B, a tiling display device TD having a large screen size can be implemented by connecting a plurality of display devices 100 such as the display device 100 of FIGS. 1 and 2A. At this time, as illustrated in FIG. 2A, when the tiling display device TD is implemented using the display devices 100 each with a minimized bezel, a seam area in which an image between the display devices TD is not displayed is minimized so that a display quality can be improved.

For example, the plurality of sub pixels SP can form one pixel PX and a distance D1 between an outermost pixel PX of one display device 100 and an outermost pixel PX of another display device 100 adjacent to the one display device can be implemented to be equal to a distance D1 between pixels PX in one display device 100. Accordingly, the distance D1 between such pixels PX between the display devices 100 is constantly set and configured to minimize the seam area. For instance, the two distances D1 and D1 marked in FIG. 2B are the same.

As an example, FIGS. 2A and 2B are illustrative so that the display device according to the aspects of the present disclosure can be a general display device with a bezel, but is not limited thereto.

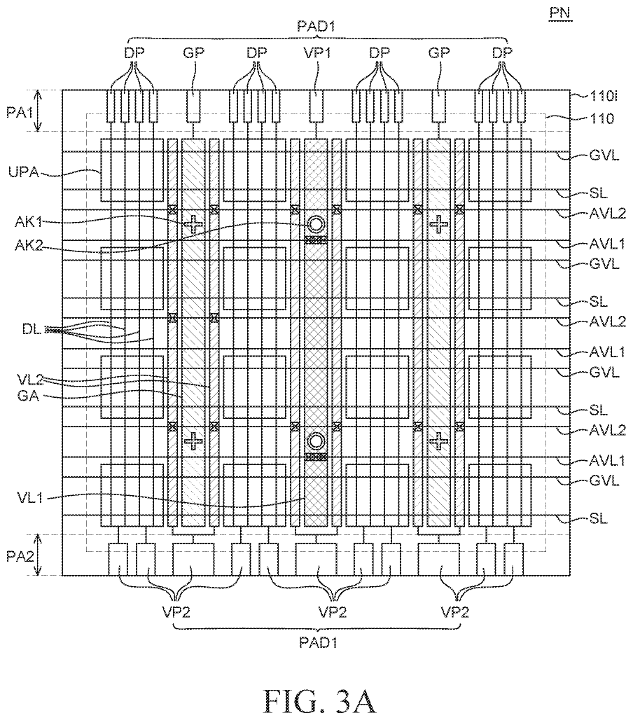

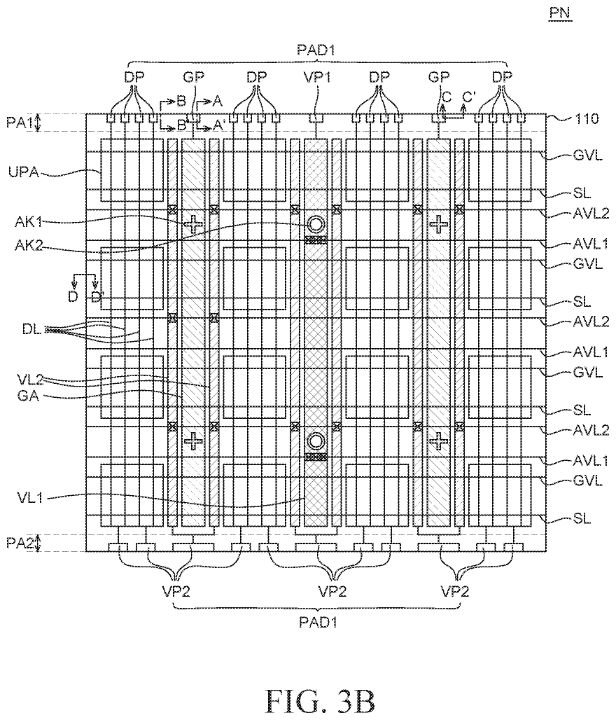

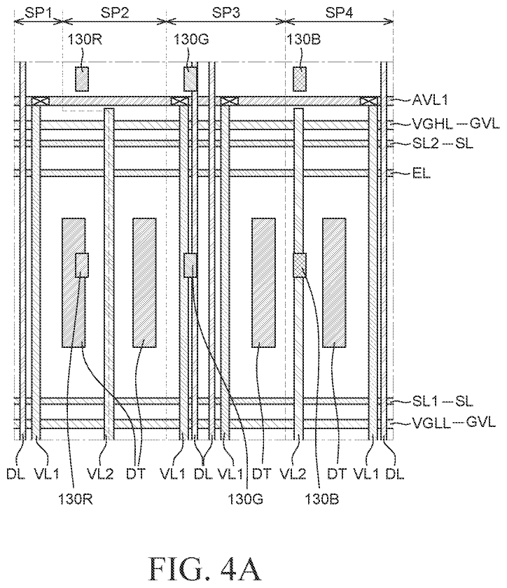

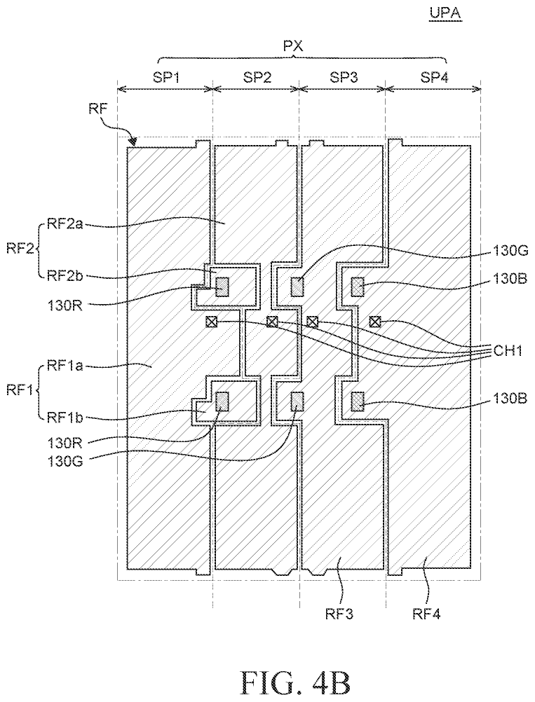

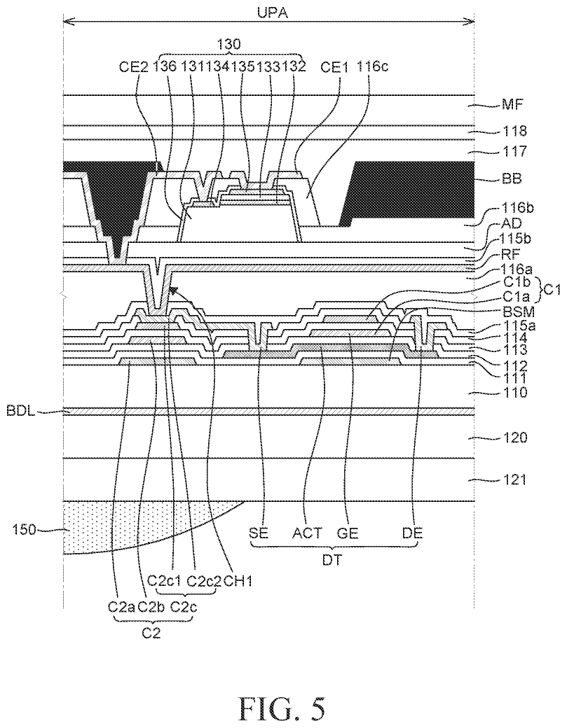

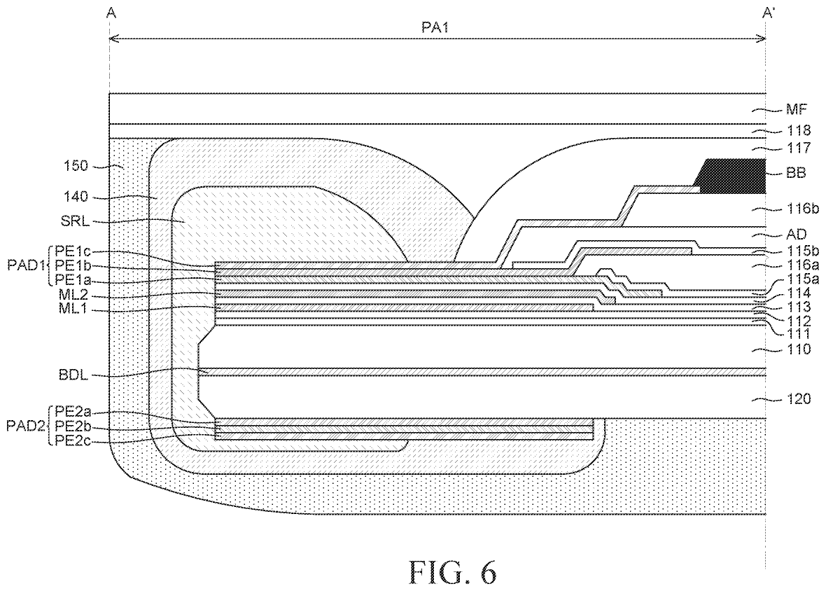

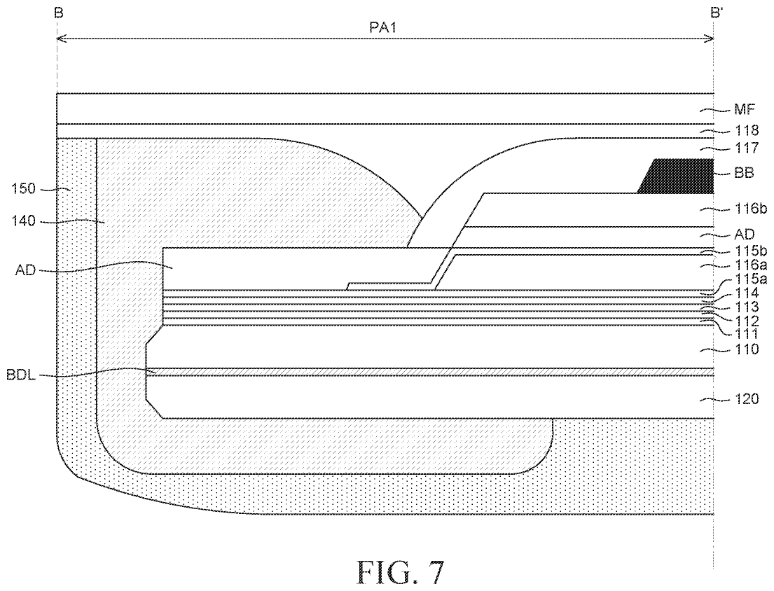

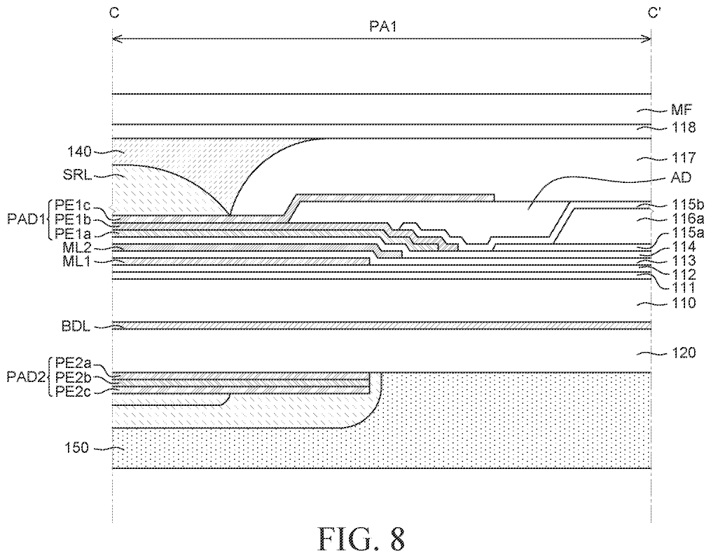

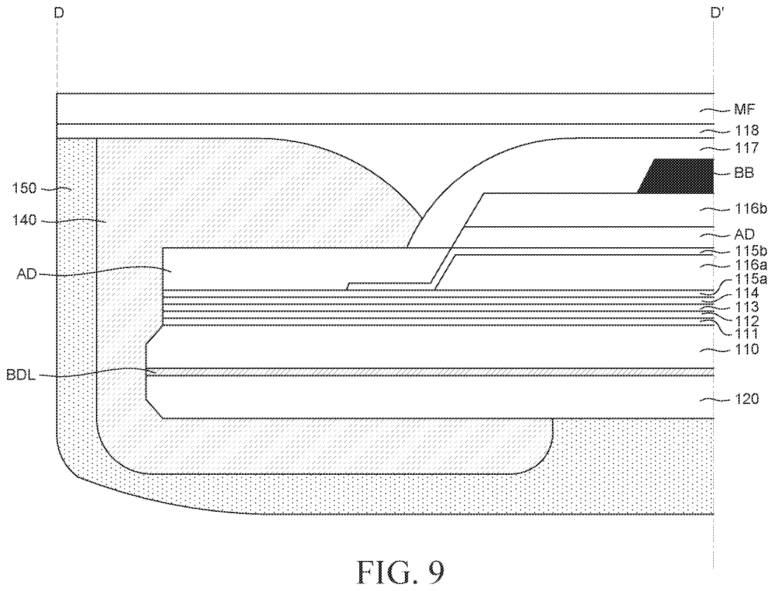

FIG. 3A is a plan view of a display panel before grinding of a display device according to an exemplary embodiment of the present disclosure. FIG. 3B is a plan view of the display panel of FIG. 3A after the grinding of the display device according to an exemplary embodiment of the present disclosure. FIGS. 4A and 4B are plan views illustrating a pixel area of a display device according to an exemplary embodiment of the present disclosure. FIG. 5 is a cross-sectional view of a pixel area of a display device according to an exemplary embodiment of the present disclosure. FIG. 6 is a cross-sectional view taken along line A-A′ of FIG. 3B. FIG. 7 is a cross-sectional view taken along line B-B′ of FIG. 3B. FIG. 8 is a cross-sectional view taken along line C-C′ of FIG. 3B. FIG. 9 is a cross-sectional view taken along line D-D′ of FIG. 3B.

For the convenience of description, in FIG. 4A, the plurality of light emitting diodes 130R, 130G, and 130B, a driving transistor DT of the pixel circuit, and a plurality of wiring lines are illustrated. In FIG. 4B, a plurality of reflection plates RF and a plurality of light emitting diodes 130R, 130G, and 130B, are illustrated. FIGS. 6 to 8 are cross-sectional views for explaining a first pad area PA1 of a display device 100 according to an exemplary embodiment of the present disclosure and FIG. 9 is a cross-sectional view for explaining a non-active area NA other than a plurality of pad areas of a display device 100 according to an exemplary embodiment of the present disclosure. The display device 100 of FIGS. 1-2B can be the display device 100 of FIGS. 6-9.

First, referring to FIGS. 3A to 9, a display panel PN of the display device includes a first substrate 110. The first substrate 110 is a substrate which supports components disposed above the display device 100 and can be an insulating substrate. A plurality of pixels PX are formed on the first substrate 110 to display images. For example, the first substrate 110 can be formed of glass, resin, or the like. Further, the first substrate 110 can include polymer or plastic. In some exemplary embodiments, the first substrate 110 can be formed of a plastic material having flexibility so the substrate can be bendable or rollable.

Referring to FIGS. 3A and 3B, in the first substrate 110 of the display panel PN, a plurality of pixel areas UPA, a plurality of gate driving areas GA, and a plurality of pad areas PA1 and PA2 are disposed. Among them, the plurality of pixel areas UPA and the plurality of gate driving areas GA can be included in the active area AA of the display panel PN.

First, the plurality of pixel areas UPA are areas in which the plurality of pixels PX are disposed. The plurality of pixel areas UPA can be disposed by forming or arranging them in a plurality of rows and a plurality of columns. Each of the plurality of pixels PX disposed in the plurality of pixel areas UPA includes a plurality of sub pixels SP. Each of the plurality of sub pixels SP includes a light emitting diode 130 and a pixel circuit for driving the light emitting diode 130 so as to independently emit light.

The plurality of gate driving areas GA are areas where gate drivers GD are disposed. The gate drivers GD can be mounted in the active area AA in a gate in active area (GIA) manner. For example, the gate driving area GA can be formed along a row direction and/or column direction between the plurality of pixel areas UPA. The gate driver GD formed in the gate driving area GA can supply the scan signal to the plurality of scan lines SL.

The gate driver GD disposed in the gate driving area GA can include a circuit for outputting a scan signal. At this time, the gate driver can include, for example, a plurality of transistors and/or capacitors. Here, active layers of the plurality of transistors can be formed of a semiconductor material, such as an oxide semiconductor, amorphous silicon, or polysilicon, but are not limited thereto. The active layers of the plurality of transistors can be formed of the same material or different materials from each other. Further, the active layers of the transistors of the gate driver can be formed of the same material as active layers of various transistors of the pixel circuit or formed of different materials from each other.

The plurality of pad areas PA1 and PA2 are disposed in the non-active area NA, which can be disposed, as an example, at an upper side and a lower side of the display panel PN. The plurality of pad areas PA1 and PA2 are areas in which a plurality of first pad electrodes PAD1 are disposed. The plurality of first pad electrodes PAD1 can transmit various signals to various wiring lines extending in a column direction in the active area AA. For example, the plurality of first pad electrodes PAD1 include one or more data pads DP, one or more gate pads GP, one or more high potential power pads VP1, and one or more low potential power pads VP2. The data pad DP transmits a data voltage to the data line DL and the gate pad GP transmits a clock signal, a start signal, a gate low voltage, a gate high voltage, and the like for driving the gate driver GD to the gate driver GD. The high potential power pad VP1 transmits a high potential power voltage to the high potential power line VL1, whereas the low potential power pad VP2 transmits a low potential power voltage to the low potential power line VL2.

The plurality of pad areas PA1 and PA2 include a first pad area PA1 located at an upper edge of the display panel PN and a second pad area PA2 located at a lower edge of the display panel PN. In the first pad area PA1 and the second pad area PA2, the plurality of first pad electrode PAD1 are disposed to transmit a signal to the plurality of sub pixels SP. At this time, in the first pad area PA1 and the second pad area PA2, different types of first pad electrodes PAD1 can be disposed. For example, in the first pad area PA1, among the plurality of first pad electrodes PAD1, the data pad DP, the gate pad GP, and the high potential power pad VP1 can be disposed and in the second pad area PA2, the low potential power pad VP2 can be disposed.

At this time, the plurality of first pad electrodes PAD1 can be formed to have different sizes, respectively. For example, the plurality of data pads DP which are connected to the plurality of data lines DL one to one can have a smaller width, and the high potential power pad VP1, the low potential power pad VP2, and the gate pad GP can have a larger width. However, widths of the data pad DP, the gate pad GP, the high potential power pad VP1, and the low potential power pad VP2 illustrated in FIGS. 3A and 3B are examples only so that the first pad electrode PAD1 can be configured in various sizes, but is not limited thereto.

In the meantime, in order to reduce the bezel of the display panel PN, an edge of the display panel PN can be cut to be removed. For example, as illustrated in FIG. 3A, the plurality of pixels PX, the plurality of wiring lines, and the plurality of first pad electrodes PAD1 are formed on an initial first substrate 110i.

Then as illustrated in FIG. 3B, an edge part of the initial first substrate 110i is grinded or ground to reduce the bezel area of the display panel PN. For instance, during the grinding process, a part of the initial first substrate 110i is removed (or cut out) to form the first substrate 110 with a smaller size as shown in FIG. 3B. At this time, parts of the plurality of first pad electrodes PAD1 and wiring lines disposed at the edge of the first substrate 110 can be cut out or removed. Accordingly, only a part of the plurality of first pad electrodes PAD1 can remain on the first substrate 110.

Next, the plurality of data lines DL which extend in a column direction or a set direction from the plurality of first pad electrodes PAD1 are disposed on the first substrate 110 of the display panel PN. The plurality of data lines DL can extend from the plurality of data pads DP of the first pad area PA1 toward the plurality of pixel areas UPA. The plurality of data lines DL can extend in a column direction and can be disposed to overlap the plurality of pixel areas UPA. Therefore, the plurality of data lines DL can transmit the data voltage to the pixel circuit of each of the plurality of sub pixels SP.

The plurality of high potential power lines VL1 extending in the column direction are disposed on the first substrate 110 of the display panel PN. Some of the plurality of high potential power lines VL1 extend from the high potential power pad VP1 of the first pad area PA1 to the plurality of pixel areas UPA to transmit the high potential power voltage to the light emitting diode 130 of each of the plurality of sub pixels SP. The others of the plurality of high potential power lines VL1 can be electrically connected to the other high potential power line VL1 by an auxiliary high potential power line AVL1 to be described below. In FIGS. 3A and 3B, for the convenience of description, one high potential power line VL1 and one high potential power pad VP1 are disposed, but a plurality of high potential power lines VL1 and high potential power pads VP1 can be disposed.

The plurality of low potential power lines VL2 extending in the column direction are disposed on the first substrate 110 of the display panel PN. At least some of the plurality of low potential power lines VL2 extend from the low potential power pad VP2 of the second pad area PA2 to the plurality of pixel areas UPA to transmit the low potential power voltage to the pixel circuit of each of the plurality of sub pixels SP. The others of the plurality of low potential power lines VL2 can be electrically connected to the other low potential power line VL2 by an auxiliary low potential power line AVL2 to be described below.

The plurality of scan lines SL extending in the row direction are disposed on the first substrate 110 of the display panel PN. The plurality of scan lines SL extend in the row direction (or other set direction) and can be disposed across the plurality of pixel areas UPA and the plurality of gate driving areas GA. The plurality of scan lines SL can transmit the scan signal from the gate driver GD to the pixel circuits of the plurality of sub pixels SP.

A plurality of auxiliary high potential power lines AVL1 extending in the row direction are disposed on the first substrate 110 of the display panel PN. The plurality of auxiliary high potential power lines AVL1 can be disposed in an area between the plurality of pixel areas UPA. The plurality of auxiliary high potential power lines AVL1 extending in the row direction are electrically connected to the plurality of high potential power lines VL1 extending in the column direction through a contact hole and can form a mesh structure. Therefore, the plurality of auxiliary high potential power lines AVL1 and the plurality of high potential power lines VL1 are configured to form a mesh structure to minimize voltage drop and voltage deviation.

Further, a plurality of auxiliary low potential power lines AVL2 extending in the row direction are disposed on the first substrate 110 of the display panel PN. The plurality of auxiliary low potential power lines AVL2 can be disposed in an area between the plurality of pixel areas UPA. The plurality of auxiliary low potential power lines AVL2 extending in the row direction are electrically connected to the plurality of low potential power lines VL2 extending in the column direction through a contact hole to form a mesh structure. Therefore, the plurality of auxiliary low potential power lines AVL2 and the plurality of low potential power lines VL2 are configured to form a mesh structure to reduce a resistance of the wiring line and minimize voltage deviation.

Referring to FIGS. 3A and 4A, the plurality of gate driving lines extending in the row direction and the column direction are disposed on the first substrate 110 of the display panel PN. Some of the plurality of gate driving lines extend from the gate pad GP of the first pad area PA1 to the gate driving area GA to transmit a signal to the gate driver GD. The others of the plurality of gate driving lines can extend in the row direction and transmit the signal to the gate drivers GD of the plurality of gate driving areas GA. Therefore, various signals are transmitted from the gate driving line to the gate driver GD to drive the gate driver GD.

The plurality of gate driving lines can include wiring lines which transmit a clock signal, a start signal, a gate high voltage, a gate low voltage, and the like to the gate driver GD. Therefore, various signals are transmitted from the gate driving line to the gate driver GD to drive the gate driver GD.

For example, referring to FIG. 4A, the plurality of gate driving lines can include one or more gate power lines GVL extending in the row direction, which transmits a power voltage to the gate driver GD of the gate driving area GA. The plurality of gate power lines GVL include a first gate power line VGHL which transmits a gate high voltage to the gate driver GD and a second gate power line VGLL which transmits a gate low voltage to the gate driver GD.

Further, returning to FIG. 3B, a plurality of alignment keys AK1 and AK2 are disposed in an area between the plurality of pixel areas UPA in the display panel PN. The plurality of alignment keys AK1 and AK2 are used for alignment during the manufacturing process of the display panel PN. The plurality of alignment keys AK1 and AK2 include one or more first alignment keys AK1 and one or more second alignment keys AK2.

The first alignment key AK1 can be disposed in the gate driving area GA between the plurality of pixel areas UPA. The first alignment key AK1 can be used to inspect an alignment position of the plurality of light emitting diodes 130 (such as 130R, 130G, 130B in FIG. 4A). For example, the first alignment key AK1 can have a cross shape, but is not limited thereto.

The second alignment key AK2 can be disposed to overlap the high potential power line VL1 of an area between the plurality of pixel areas UPA. In the high potential power line VL1, a hole overlapping the second alignment key AK2 is formed to divide the second alignment key AK2 and the high potential power line VL1. The second alignment key AK2 can be used to align the display panel PN and a donor. The display panel PN and the donor are aligned using the second alignment key AK2 and the plurality of light emitting diodes 130 of the donor can be transferred onto the display panel PN. For example, the second alignment key AK2 can have a circular ring shape, but is not limited thereto.

Hereinafter, the plurality of sub pixels SP of the pixel area UPA will be described in more detail with reference to FIGS. 4A to 5. The UPA of FIGS. 4A to 5 can be the UPA of FIG. 3B as an example.

Referring to FIGS. 4A and 4B, in one pixel area UPA, a plurality of sub pixels SP which form one pixel PX are disposed. For example, the plurality of sub pixels SP can include a first sub pixel SP1, a second sub pixel SP2, a third sub pixel SP3, and a fourth sub pixel SP4 which emit different color lights. For example, the first sub pixel SP1 and the second sub pixel SP2 can be red sub sub pixels, the third sub pixel SP3 can be a green sub pixel, and the fourth sub pixel SP4 can be a blue sub pixel, but it is not limited thereto and other variations are possible.

Hereinafter, the description will be made by assuming that one pixel PX includes one first sub pixel SP1, one second sub pixel SP2, one third sub pixel SP3, and one fourth sub pixel SP4, for example, two red sub pixels, one green sub pixel, and one blue sub pixel. However, the configuration of the pixel PX is not limited thereto, and other variations or combinations of different sub pixels for forming a pixel PX are possible.

Referring to FIG. 4A, as described above, a plurality of wiring lines which supply various signals to the plurality of sub pixels SP are disposed in the plurality of pixel areas UPA of the first substrate 110. For example, the plurality of data lines DL, the plurality of high potential power lines VL1, and the plurality of low potential power lines VL2 extending in the column direction can be disposed on the first substrate 110. Further, the plurality of emission control signal lines EL, the plurality of auxiliary high potential power lines AVL1, the plurality of auxiliary low potential power lines AVL2, the plurality of first scan lines SL1, and the plurality of second scan lines SL2 extending in the row direction can be disposed on the first substrate 110. The high potential power line VL1 extending in the column direction can be electrically connected to the auxiliary high potential power line AVL1 extending in the row direction through a contact hole. At this time, the emission control signal line transmits an emission control signal to the pixel circuits of the plurality of sub pixels SP to control an emission timing of each of the plurality of sub pixels SP.

Some gate power lines GVL which transmit a signal to each of the plurality of gate drivers GD disposed to be spaced apart from each other with the pixel area UPA therebetween can be disposed across the pixel area UPA while extending in the row direction. For example, a first gate power line VGHL which supplies a gate high voltage (high-level gate voltage signal) to the gate driver GD and a second gate power line VGLL which supplies a gate low voltage (low-level gate voltage signal) can be disposed across the pixel area UPA.

In the meantime, the plurality of scan lines SL include a first scan line SL1 and a second scan line SL2 in an example, but the configuration of the plurality of scan lines SL can vary depending on the pixel circuit configuration of the sub pixel SP, and is not limited thereto.

The pixel circuit for driving the light emitting diode 130 is disposed in each of the plurality of sub pixels SP on the first substrate 110. The pixel circuit can include a plurality of thin film transistors and a plurality of capacitors. In FIGS. 4A and 5, for the convenience of description, a driving transistor DT, a first capacitor C1, and a second capacitor C2, among configurations of the pixel circuit, are illustrated. However, the pixel circuit can further include a switching transistor, a sensing transistor, an emission control transistor, and the like, but is not limited thereto.

Referring to FIG. 5, first, a light shielding layer BSM is disposed on the first substrate 110. The light shielding layer BSM blocks light which is incident to an active layer of the plurality of transistors to minimize or prevent a leakage current. For example, the light shielding layer BSM is disposed below the active layer ACT of the driving transistor DT to block light incident onto the active layer ACT. If light is irradiated onto the active layer ACT, a leakage current may be generated, which may deteriorate the reliability of the transistor. Accordingly, the light shielding layer BSM which blocks the light is disposed on the first substrate 110 to improve the reliability of the driving transistor DT. The light shielding layer BSM can be formed of an opaque conductive material such as copper (Cu), aluminum (Al), molybdenum (Mo), nickel (Ni), titanium (Ti), chrome (Cr), or an alloy thereof, but is not limited thereto.

A buffer layer 111 is disposed on the light shielding layer BSM. The buffer layer 111 can reduce permeation of moisture or impurities through the first substrate 110. For example, the buffer layer 111 can be configured by a single layer or a double layer of silicon oxide SiOx or silicon nitride SiNx, but is not limited thereto. However, the buffer layer 111 can be omitted depending on a type of the first substrate 110 or a type of the thin film transistor, but is not limited thereto.

In the meantime, an additional buffer layer can be disposed between the first substrate 110 and the light shielding layer BSM. The additional buffer layer can be configured by a single layer or a double layer of silicon oxide SIOx or silicon nitride SiNx to reduce permeation of moisture or impurities through the first substrate 110, like the buffer layer 111 described above.

A driving transistor DT including an active layer ACT, a gate electrode GE, a source electrode SE, and a drain electrode DE is disposed on the buffer layer 111.

For instance, first, the active layer ACT of the driving transistor DT is disposed on the buffer layer 111. The active layer ACT can be formed of a semiconductor material such as an oxide semiconductor, amorphous silicon, or polysilicon, but is not limited thereto. Further, other transistors, such as a switching transistor, a sensing transistor, and an emission control transistor, other than the driving transistor DT, can be further disposed. The active layers of the transistors can be also formed of a semiconductor material, such as an oxide semiconductor, amorphous silicon, or polysilicon, but are not limited thereto. The active layer of the transistor included in the pixel circuit, such as the driving transistor DT, the switching transistor, the sensing transistor, and the emission control transistor, can be formed of the same material, or formed of different materials.

A gate insulating layer 112 is disposed on the active layer ACT. The gate insulating layer 112 is an insulating layer which electrically insulates the active layer ACT from the gate electrode GE and can be configured by a single layer or a double layer of silicon oxide SiOx or silicon nitride SiNx, but is not limited thereto.

The gate electrode GE is disposed on the gate insulating layer 112. The gate electrode GE can be formed of a conductive material, such as copper (Cu), aluminum (Al), molybdenum (Mo), nickel (Ni), titanium (Ti), chrome (Cr), or an alloy thereof, but is not limited thereto.

A first interlayer insulating layer 113 and a second interlayer insulating layer 114 are disposed on the gate electrode GE. In the first interlayer insulating layer 113 and the second interlayer insulating layer 114, contact holes through which the source electrode SE and the drain electrode DE are connected to the active layer are formed. The first interlayer insulating layer 113 and the second interlayer insulating layer 114 are insulating layers which protect components therebelow and can be configured by single layers or double layers of silicon oxide SiOx or silicon nitride SiNx, but are not limited thereto.

The source electrode SE and the drain electrode DE which are electrically connected to the active layer ACT are disposed on the second interlayer insulating layer 114. The source electrode SE is connected to the second capacitor C2 and the first electrode 134 of the light emitting diode 130 and the drain electrode DE is connected to the other configuration of the pixel circuit. The source electrode SE and the drain electrode DE can be formed of a conductive material, such as copper (Cu), aluminum (Al), molybdenum (Mo), nickel (Ni), titanium (Ti), chrome (Cr), or an alloy thereof, but are not limited thereto.

Next, the first capacitor C1 is disposed on the gate insulating layer 112. The first capacitor C1 includes a 1-1-th capacitor electrode C1a and a 1-2-th capacitor electrode C1b.

First, the 1-1-th capacitor electrode C1a is disposed on the gate insulating layer 112. The 1-1-th capacitor electrode C1a can be integrally formed with the gate electrode GE of the driving transistor DT.

The 1-2-th capacitor electrode C1b is disposed on the first interlayer insulating layer 113. The 1-2-th capacitor electrode C1b is disposed to overlap the 1-1-th capacitor electrode C1a with the first interlayer insulating layer 113 therebetween.

Therefore, the first capacitor C1 is connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1-th capacitor electrode C2a, a 2-2-th capacitor electrode C2b, and a 2-3-th capacitor electrode C2c. The second capacitor C2 includes the 2-1-th capacitor electrode C2a which is a lower capacitor electrode, the 2-2-th capacitor electrode C2b which is an intermediate capacitor electrode, and the 2-3-th capacitor electrode C2c which is an upper capacitor electrode.

The 2-1-th capacitor electrode C2a is disposed on the first substrate 110. The 2-1-th capacitor electrode C2a is disposed on the same layer as the light shielding layer BSM and can be formed of the same material or a different material.

The 2-2-th capacitor electrode C2b is disposed on the buffer layer 111 and the gate insulating layer 112. The 2-2-th capacitor electrode C2b is disposed on the same layer as the gate electrode GE and can be formed of the same material.

The 2-3-th capacitor electrode C2c is disposed on the first interlayer insulating layer 113. The 2-3-th capacitor electrode C2c can be configured by a first layer and a second layer. The first layer C2c1 of the 2-3-th capacitor electrode C2c can be formed on the same layer as the 1-2-th capacitor electrode C1b with the same material. The first layer C2c1 can be disposed to overlap the 2-1-th capacitor electrode C2a and the 2-2-th capacitor electrode C2b with the first interlayer insulating layer 113 therebetween.

The second layer C2c2 of the 2-3-th capacitor electrode C2c is disposed on the second interlayer insulating layer 114. The second layer C2c2 is a part extending from the source electrode SE of the driving transistor DT and can be connected to the first layer C2c1 through the contact hole of the second interlayer insulating layer 114.

Accordingly, the second capacitor C2 is electrically connected between the source electrode SE of the driving transistor DT and the light emitting diode 130 to increase capacitance inherent in the light emitting diode 130 and to allow the light emitting diode 130 to emit light with a higher luminance.

Further, a first passivation layer 115a is disposed on the driving transistor DT, the first capacitor C1, and the second capacitor C2. The first passivation layer 115a is an insulating layer for protecting a configuration/structure below the first passivation layer 115a. The first passivation layer 115a can be disposed on the entire first substrate 110. For example, the first passivation layer 115a can cover the plurality of driving transistors DT to protect the driving transistors DT.

The first passivation layer 115a can be formed of an inorganic material, for example, can be formed of silicon oxide SiOx and silicon nitride SiNx, but is not limited thereto.

A first planarization layer 116a is disposed on the first passivation layer 115a. The first planarization layer 116a can be disposed to cover the first passivation layer 115a. The first planarization layer 116a can planarize an upper portion of the pixel circuit including the driving transistor DT. The first planarization layer 116a can be configured by a single layer or a double layer, and for example, formed of benzocyclobutene or an acrylic organic material, but is not limited thereto.

In addition, referring to FIGS. 4B and 5 together, in the UPA, a plurality of reflection plates RF are disposed on the first planarization layer 116a. The reflection plates RF are disposed to overlap the plurality of light emitting diodes 130. The reflection plate RF is a configuration or structure which reflects light emitted from the plurality of light emitting diodes 130 above the first substrate 110 and can be formed with a shape corresponding to each of the plurality of sub pixels SP. One reflection plate RF can be disposed to cover the most area of one sub pixel SP.

The reflection plate RF reflects the light emitted from the light emitting diode 130 and can be also used as an electrode which electrically connects the light emitting diode 130 and the pixel circuit. Therefore, the reflection plate RF can include various conductive layers in consideration of a light reflection efficiency and a resistance. For example, the reflection plate RF can use an opaque conductive layer such as silver (Ag), aluminum (Al), molybdenum (Mo), titanium (Ti), or an alloy thereof and a transparent conductive layer such as indium tin oxide, but the structure of the reflection plate RF is not limited thereto.

The reflection plate RF includes a first reflection plate RF1 corresponding to the first sub pixel SP1, a second reflection plate RF2 corresponding to the second sub pixel SP2, a third reflection plate RF3 corresponding to the third sub pixel SP3, and a fourth reflection plate RF4 corresponding to the fourth sub pixel SP4.

The first reflection plate RF1 includes a 1-1-th reflection plate RF1a overlapping most of the first sub pixel SP1 and a 1-2-th reflection plate RF1b overlapping the red light emitting diode 130R of the first sub pixel SP1. The 1-1-th reflection plate RF1a can reflect light emitted from the red light emitting diode 130R above the red light emitting diode 130R. The 1-1-th reflection plate RF1a can be electrically connected to the source electrode SE of the driving transistor DT and the second capacitor C2 through a first contact hole CH1 in the first planarization layer 116a and the first passivation layer 115a. Therefore, the 1-1-th reflection plate RF1a can electrically connect the driving transistor DT and the first electrode 134 of the red light emitting diode 130R. The 1-2-th reflection plate RF1b can reflect light emitted from the red light emitting diode 130R above the red light emitting diode 130R. The 1-2-th reflection plate RF1b can serve as an electrode which electrically connects the second electrode 135 of the red light emitting diode 130R and the high potential power line VL1.

The second reflection plate RF2 includes a 2-1-th reflection plate RF2a overlapping most of the second sub pixel SP2 and a 2-2-th reflection plate RF2b overlapping the red light emitting diode 130R of the second sub pixel SP2. The 2-1-th reflection plate RF2a can reflect light emitted from the red light emitting diode 130R above the red light emitting diode 130R. The 2-1-th reflection plate RF2a is electrically connected to the source electrode SE of the driving transistor DT and the second capacitor C2 through the first contact hole CH1 to transmit a driving current from the driving transistor DT to the first electrode 134 of the red light emitting diode 130R. The 2-2-th reflection plate RF2b can be used as an electrode which reflects the light emitted from the red light emitting diode 130R above the red light emitting diode 130R and electrically connects the second electrode 135 of the red light emitting diode 130R to the high potential power line VL1.

The third reflection plate RF3 can be formed as one third reflection plate RF3 which overlaps the entire third sub pixel SP3. The third reflection plate RF3 can reflect light emitted from the green light emitting diode 130G of the third sub pixel SP3 above the green light emitting diode 130G. The third reflection plate RF3 is electrically connected to the source electrode SE of the driving transistor DT and the second capacitor C2 through the first contact hole CH1 to transmit a driving current from the driving transistor DT to the first electrode 134 of the green light emitting diode 130G.

The fourth reflection plate RF4 can be formed as one fourth reflection plate RF4 which overlaps the entire fourth sub pixel SP4. The fourth reflection plate RF4 can reflect light emitted from the blue light emitting diode 130B of the fourth sub pixel SP4 above the blue light emitting diode 130B. The fourth reflection plate RF4 is electrically connected to the source electrode SE of the driving transistor DT and the second capacitor C2 through the first contact hole CH1 to transmit a driving current from the driving transistor DT to the first electrode 134 of the blue light emitting diode 130B.

In the meantime, even though it has been described that the first sub pixel SP1 and the second sub pixel SP2 are formed with two reflection plates RF while the third sub pixel SP3 and the fourth sub pixel SP4 are formed with one reflection plate RF, the reflection plate RF can be designed in various manners. For example, only one reflection plate RF can be disposed in all the plurality of sub pixels SP, such as the third sub pixel SP3 and the fourth sub pixel SP4, or a plurality of reflection plates RF can be disposed in all the sub pixels, such as the first sub pixel SP1 and the second sub pixel SP2l. However, the configuration of the reflection plate is not limited thereto and other variations are possible as part of the present disclosure.

Further, the red light emitting diode 130R of each of the first sub pixel SP1 and the second sub pixel SP2 is electrically connected to the high potential power line VL1 through the 1-2-th reflection plate RF1b and the 2-2-th reflection plate RF2b. However, all the red light emitting diode 130R, the green light emitting diode 130G, and the blue light emitting diode 130B can be separately connected to the high potential power line VL1 without the reflection plate RF, and are not limited thereto.

Now referring back to FIG. 5 to continue to describe the structure of the UPA there, the second passivation layer 115b is disposed on the plurality of reflection plates RF. The second passivation layer 115b is an insulating layer for protecting a configuration below the second passivation layer 115b. The second passivation layer 115b can be disposed on the entire first substrate 110. For example, the second passivation layer can be disposed to cover the plurality of reflection plates RF and the first planarization layer 116a.

The second passivation layer 115b can be formed of an inorganic material. For example, the second passivation layer 115b can be configured by a single layer or a double layer of silicon oxide SiOx or silicon nitride SiNx, but is not limited thereto.

An adhesive layer AD is disposed on the second passivation layer 115b. The adhesive layer AD is formed on the entire surface of the first substrate 110 to fix the light emitting diode 130 (e.g., 130R, 130G, 130B, etc.) disposed on the adhesive layer AD. The adhesive layer AD can be formed of a photo curable adhesive material which is cured by light. For example, the adhesive layer AD can be formed of an acrylic material including a photoresist, but is not limited thereto. The adhesive layer AD can be formed on the entire surface of the first substrate 110 excluding a part of the pad areas PA1 and PA2 in which the first pad electrode PAD1 is disposed.

The plurality of light emitting diodes 130 are disposed in each of the plurality of sub pixels SP on the adhesive layer AD, respectively. The light emitting diode 130 is an element which emits light by a current and can include a red light emitting diode 130R which emits red light, a green light emitting diode 130G which emits green light, and a blue light emitting diode 130B which emits blue light. The light emitting diode 130 can implement light with various colors including white by a combination thereof. For example, the light emitting diode 130 can be a light emitting diode (LED) or a micro LED, but is not limited thereto. The light emitting diode 130 can preferably include an inorganic material.

One red light emitting diode 130R is disposed in each of the first sub pixel SP1 and the second sub pixel SP2, one pair of green light emitting diodes 130G is disposed in the third sub pixel SP3, and one pair of blue light emitting diodes 130B is disposed in the fourth sub pixel SP4. For example, two red light emitting diodes 130R, two green light emitting diodes 130G, and two blue light emitting diodes 130B can be disposed in each one pixel PX. At this time, each of the red light emitting diodes 130R is connected to the driving transistor DT of each of the first sub pixel SP1 and the second sub pixel SP2 to be individually driven. In contrast, one pair of green light emitting diodes 130G of the third sub pixel SP3 and one pair of blue light emitting diodes 130B of the fourth sub pixel SP4 can be connected to one driving transistor DT in parallel to be driven. However, the present disclosure is not limited to it. The number and the color of the sub pixels disposed in each pixel PX can be different from the above configuration.

The plurality of light emitting diodes 130 are disposed on the adhesive layer AD. Each light emitting diodes 130 includes a first semiconductor layer 131, an emission layer 132, a second semiconductor layer 133, a first electrode 134, and a second electrode 135.

The first semiconductor layer 131 is disposed on the adhesive layer AD and the second semiconductor layer 133 is disposed on the first semiconductor layer 131. The first semiconductor layer 131 and the second semiconductor layer 133 can be layers formed by doping n-type and p-type impurities into a specific material. For example, the first semiconductor layer 131 and the second semiconductor layer 133 can be layers doped with n-type and p-type impurities into a material such as gallium nitride (GaN), indium aluminum phosphide (InAlP), or gallium arsenide (GaAs). The p-type impurity can be magnesium (Mg), zinc (Zn), beryllium (Be), and the like, and the n-type impurity can be silicon (Si), germanium, tin (Sn), and the like, but are not limited thereto.

The emission layer 132 is disposed between the first semiconductor layer 131 and the second semiconductor layer 133. The emission layer 132 is supplied with holes and electrons from the first semiconductor layer 131 and the second semiconductor layer 133 to emit light. The emission layer 132 can be formed by a single layer or a multi-quantum well (MQW) structure, and for example, can be formed of indium gallium nitride (InGaN) or gallium nitride (GaN), but is not limited thereto.

The first electrode 134 is disposed on the first semiconductor layer 131. The first electrode 134 is an electrode which electrically connects the driving transistor DT and the first semiconductor layer 131. In this case, the first semiconductor layer 131 is a semiconductor layer doped with an n-type impurity and the first electrode 131 can be a cathode. The first electrode 134 can be disposed on a top surface of the first semiconductor layer 131 which is exposed from the emission layer 132 and the second semiconductor layer 133. The first electrode 134 can be formed of a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

The second electrode 135 is disposed on the second semiconductor layer 133. The second electrode 135 can be disposed on the top surface of the second semiconductor layer 133. The second electrode 135 is an electrode which electrically connects the high potential power line and the second semiconductor layer 133. In this case, the second semiconductor layer 133 is a semiconductor layer doped with a p-type impurity and the second electrode 135 can be an anode. The second electrode 135 can be formed of a conductive material, for example, a transparent conductive material, such as indium tin oxide (ITO) or indium zinc oxide (IZO) or an opaque conductive material, such as titanium (Ti), gold (Au), silver (Ag), copper (Cu) or an alloy thereof, but is not limited thereto.

Next, the encapsulation layer 136 which encloses or surrounds the first semiconductor layer 131, the emission layer 132, the second semiconductor layer 133, the first electrode 134, and the second electrode 135, is disposed. The encapsulation layer 136 is formed of an insulating material to protect the first semiconductor layer 131, the emission layer 132, and the second semiconductor layer 133. In the encapsulation layer 136, a contact hole which exposes the first electrode 134 and the second electrode 135 is formed to electrically connect a first connection electrode CE1 and a second connection electrode CE2 to the first electrode 134 and the second electrode 135.

In the meantime, a part of the side surface of the first semiconductor layer 131 can be exposed from the encapsulation layer 136. The light emitting diode 130 manufactured on the wafer is separated from the wafer to be transferred onto the display panel PN. However, during the process of separating the light emitting diode 130 from the wafer, a part of the encapsulation layer 136 may be torn. For example, a part of the encapsulation layer 136 which is adjacent to a lower edge of the first semiconductor layer 131 of the light emitting diode 130 may be torn during the process of separating the light emitting diode 130 from the wafer. Accordingly, a part of a lower side surface of the first semiconductor layer 131 may be exposed to the outside. However, even though the lower portion of the light emitting diode 130 may be exposed from the encapsulation layer 136, the first connection electrode CE1 and the second connection electrode CE2 are formed after forming the second planarization layer 116b and the third planarization layer 116c, which then cover the side surface of the first semiconductor layer 131. That is, the first connection electrode CE1 and the second connection electrode CE2 end up covering the side surface of the first semiconductor layer 131 of the light emitting diode 130, which in turn protects the light emitting diode 130. Accordingly, a short defect issue associated with the light emitting diode 130 can be reduced, minimized or prevented.

Next, the second planarization layer 116b and the third planarization layer 116c are disposed on the adhesive layer AD and the light emitting diode 130.

The second planarization layer 116b overlaps a part of side surfaces of the plurality of light emitting diodes 130 to fix and protect the plurality of light emitting diodes 130. The second planarization layer 116b can be formed using a halftone mask. Therefore, the second planarization layer 116b can be formed to have a step.

Specifically, a part of the second planarization layer 116b which is relatively adjacent to the light emitting diode 130 can be formed to have a smaller thickness, whereas a part of the second planarization layer 116b which is farther from the light emitting diode 130 can be formed to have a larger thickness. A part of the second planarization layer 116b which is adjacent to the light emitting diode 130 is disposed to enclose or surround the light emitting diode 130 and also can be in contact with a side surface of the light emitting diode 130. Therefore, a torn part (if any) of the encapsulation layer 136 which protects a side surface of the first semiconductor layer 131 of the light emitting diode 130 during the process of separating the light emitting diode 130 from the wafer to be transferred onto the display panel PN can now be covered and further protected by the second planarization layer 116b. By doing this, thereafter, contacts and short defect issues associated with the connection electrodes CE1 and CE2 and the first semiconductor layer 131 can be eliminated, minimized, or suppressed according to the aspects of the present disclosure.

The third planarization layer 116c is formed to cover upper portions of the second planarization layer 116b and the light emitting diode 130 and a contact hole which exposes the first electrode 134 and the second electrode 135 of the light emitting diode 130 can be formed. The first electrode 134 and the second electrode 135 of the light emitting diode 130 are exposed from the third planarization layer 116c, and the third planarization layer 116c is partially disposed in an area between the first electrode 134 and the second electrode 135 to reduce or prevent a short defect. The second planarization layer 116b and the third planarization layer 116c can be configured by a single layer or a double layer, and for example, can be formed of photoresist or an acrylic organic material, but is not limited thereto.

In the meantime, the third planarization layer 116c can cover only the light emitting diode 130 and an area adjacent to the light emitting diode 130. The third planarization layer 116c is disposed in an area of the sub pixel SP enclosed by the bank BB and can be disposed in an island shape. Therefore, the bank BB can be disposed in a part of the top surface of the second planarization layer 116b and the third planarization layer 116c can be disposed in the other part of the top surface of the second planarization layer 116b.

The first connection electrode CE1 and the second connection electrode CE2 are disposed on the third planarization layer 116c. The first connection electrode CE1 is an electrode which electrically connects the second electrode 135 of the light emitting diode 130 and the high potential power line VL1. The first connection electrode CE1 can be electrically connected to the second electrode 135 of the light emitting diode 130 through a contact hole formed in the third planarization layer 116c.

The second connection electrode CE2 is an electrode which electrically connects the first electrode 134 of the light emitting diode 130 and the driving transistor DT. The second connection electrode CE2 can be connected to the 1-1-th reflection plate RF1a, the 1-2-th reflection plate RF1b, the third reflection plate RF3, and the fourth reflection plate RF4 of each of the plurality of sub pixels SP through contact holes formed in the third planarization layer 116c, the second planarization layer 116b, the adhesive layer AD, and the second passivation layer 115b. At this time, the 1-1-th reflection plate RF1a, the 1-2-th reflection plate RF1b, the third reflection plate RF3, and the fourth reflection plate RF4 are also connected to the source electrode SE of the driving transistor DT, so that the source electrode SE of the driving transistor DT and the first electrode 134 of the light emitting diode 130 can be electrically connected to each other.

In the meantime, the first electrode 134, the second connection electrode CE2, and the reflection plate RF are electrically connected to the source electrode SE of the driving transistor DT. However, the first electrode 134, the second connection electrode CE2, and the reflection plate RF can be connected to the drain electrode DE of the driving transistor DT, and it is not limited thereto.

The bank BB is disposed on the second planarization layer 116b exposed from the first connection electrode CE1 and the second connection electrode CE2, and the third planarization layer 116c. The bank BB can be disposed to be spaced apart from the light emitting diode 130 with a predetermined interval, and overlaps at least partially the reflection plate RF. For example, the bank BB can cover a part of the second connection electrode CE2 formed in the contact holes of the third planarization layer 116c and the second planarization layer 116b.

Further, the bank BB can be disposed on the second planarization layer 116b with a predetermined interval from the light emitting diode 130. In this case, the bank BB and the third planarization layer 116c can be spaced apart from each other on a part of the second planarization layer 116b having a smaller thickness. For example, an end of the bank BB and an end of the third planarization layer 116c can be disposed on a part of the second planarization layer 116b having a smaller thickness formed by a halftone mask process to be spaced apart from each other.

The bank BB can be formed of an opaque material to reduce color mixture between the plurality of sub pixels SP and for example, can be formed of black resin, but is not limited thereto.

In the meantime, a thickness of a part of the bank BB which is formed in the contact holes of the third planarization layer 116c and the second planarization layer 116b to cover a part of the second connection electrode CE2, and a thickness of a part disposed on the second planarization layer 116b can be different from each other. Specifically, when the part of the bank BB covers a part of the second connection electrode CE2 formed in the contact holes of the third planarization layer 116c and the second planarization layer 116b, since the contact hole is formed from the second passivation layer 115b to the third planarization layer 116c, the bank BB can be disposed below the light emitting diode 130, for example, disposed to be lower than the light emitting diode 130. Therefore, the thickness of the part of the bank BB which covers a part of the second connection electrode CE2 formed in the contact holes of the third planarization layer 116c and the second planarization layer 116b can be larger than the thickness of a part of the bank BB disposed on the second planarization layer 116b.

A first protection layer 117 is disposed on the first connection electrode CE1, the second connection electrode CE2, and the bank BB. The first protection layer 117 is a layer for protecting components below the first protection layer 117, and can be configured by a single layer or a double layer of translucent epoxy, silicon oxide SiOx or silicon nitride SiNx, but is not limited thereto. Further, an adhering unit 118 and an optical film MF are disposed on the first protection layer 117, which will be discussed later in more detail.

Now, the non-active area NA and the plurality of pad areas PA1 and PA2 of the display device 100 according to aspects of the present disclosure will be described in more detail with reference to FIGS. 6 to 9. As a review, FIG. 6 is a cross-sectional view taken along line A-A′ of FIG. 3B; FIG. 7 is a cross-sectional view taken along line B-B′ of FIG. 3B; FIG. 8 is a cross-sectional view taken along line C-C′ of FIG. 3B; and FIG. 9 is a cross-sectional view taken along line D-D′ of FIG. 3B.

Referring to FIGS. 6 to 9, the plurality of first pad electrodes PAD1 are disposed in the first pad area PA1 and the second pad area PA2 of the first substrate 110. Each of the plurality of first pad electrodes PAD1 can be configured by a plurality of conductive layers. For example, each of the plurality of first pad electrodes PAD1 includes a first conductive layer PE1a, a second conductive layer PE1b on the first conductive layer PE1a, and a third conductive layer PE1c on the second conductive layer PE1b.

First, the first conductive layer PE1a is disposed on the second interlayer insulating layer 114. The first conductive layer PE1a can be formed of the same material as the source electrode SE and the drain electrode DE. The first conductive layer PE1a can be formed of a conductive material such as copper (Cu), aluminum (Al), molybdenum (Mo), nickel (Ni), titanium (Ti), chrome (Cr), or an alloy thereof, but is not limited thereto.

The first passivation layer 115a is disposed on the first conductive layer PE1a. The passivation layer 115a extends from the active area AA to the non-active area NA. Referring to FIG. 6, the first passivation layer 115a is disposed so as to cover an end of the first conductive layer PE1a in an area overlapping the plurality of first pad electrodes PAD1. Referring to FIGS. 7 and 9, the first passivation layer 115a can extend to be disposed to an area of the non-active area which does not overlap the plurality of first pad electrode PAD1, for example, between the plurality of first pad electrodes PAD1 and an outermost side of a top surface of the first substrate 110 in the left and right non-active areas NA of the first substrate 110 or in two opposite non-active areas NA of the first substrate 110.

The first planarization layer 116a is disposed on the first conductive layer PE1a and the first passivation layer 115a. Referring to FIG. 6, the first planarization layer 116a covers an end of the first passivation layer 115a in an area overlapping the plurality of first pad electrodes PAD1. Therefore, the first planarization layer 116a covers the first passivation layer 115a to suppress the damage to be caused in the first passivation layer 115a which is an inorganic insulating layer during a subsequent process.

In the meantime, the first planarization layer 116a which extends from the active area AA to the plurality of pad areas PA1 and PA2 of the non-active area NA can be disposed to be spaced apart from the plurality of first pad electrodes PAD1 in a peripheral portion of the plurality of first pad electrodes PAD1. For example, referring to FIG. 8, the first planarization layer 116a is spaced apart from the first pad electrode PAD1 between the plurality of first pad electrodes PAD1 of the first pad area PA1. Further, the first passivation layer 115a and the second passivation layer 115b are disposed to be in contact with each other in an area in which the plurality of first pad electrodes PAD1 and the first planarization layer 116a are spaced apart from each other. Therefore, the first planarization layer 116a is not in contact with the plurality of first pad electrodes PAD1 in the peripheral portion of the plurality of first pad electrodes PAD1 and the first planarization layer 116a is enclosed by the first passivation layer 115a and the second passivation layer 115b. Therefore, the permeation to the first pad electrode PAD1 due to the first planarization layer 116a which is an organic material can be minimized or prevented.

The second conductive layer PE1b is disposed on the first conductive layer PE1a, the first passivation layer 115a, and the first planarization layer 116a. The second conductive layer PE1b can be formed of the same material as the reflection plate RF. The second conductive layer PE1b can be formed of a conductive material and for example, can be formed of silver (Ag), aluminum (Al), molybdenum (Mo), or an alloy thereof, but is not limited thereto.

The second passivation layer 115b is disposed on the second conductive layer PE1b and the first planarization layer 116a. The second passivation layer 115b extends from the active area AA to the non-active area NA to cover the first planarization layer 116a.

Referring to FIG. 6, the second passivation layer 115b is disposed to cover one end of the second conductive layer PE1b in an area overlapping the plurality of first pad electrodes PAD1 and is disposed to be in contact with the first passivation layer 115a.

Referring to FIG. 7, the second passivation layer 115b covers the first planarization layer 116a in an area between the plurality of first pad electrodes PAD1 and an end of the second passivation layer 115b is disposed on the first passivation layer 115a. For example, the first passivation layer 115a and the second passivation layer 115b are disposed so as to be in contact with each other in an area overlapping the plurality of first pad electrodes PAD1.

Referring to FIG. 9, the first passivation layer 115a and the second passivation layer 115b are disposed to be in contact with each other also in left and right non-active areas NA of the first substrate 110 or in two opposite non-active areas NA of the first substrate 110. Therefore, the first passivation layer 115a and the second passivation layer 115b can be disposed to have a structure which seals the end of the first planarization layer 116a while being in contact with each other in all the non-active areas NA.

An adhesive layer AD is disposed on the second passivation layer 115b. The adhesive layer AD extends from the pixel area UPA to the non-active area NA. Referring to FIGS. 6 to 9, the end of the adhesive layer AD is disposed at the outside from the end of the first planarization layer 116a in the non-active area NA. Therefore, the adhesive layer AD can alleviate the step by the first planarization layer 116a.

Referring to FIG. 6, the adhesive layer AD is disposed to cover an end of the second passivation layer 115b in an area overlapping the plurality of first pad electrodes PAD1. Referring to FIGS. 7 and 9, the adhesive layer AD is disposed so as to cover an end of the second passivation layer 115b in an area between the plurality of first pad electrodes PAD1 and in the left and right non-active areas NA of the first substrate 110. Therefore, the adhesive layer AD can buffer and protect the end of the second passivation layer 115b which is an inorganic material by covering the end of the second passivation layer 115b.

The third conductive layer PE1c is disposed on the second conductive layer PE1b and the adhesive layer AD. The third conductive layer PE1c is formed of the same material as the first connection electrode CE1 and the second connection electrode CE2. The third conductive layer PE1c can be formed of a transparent conductive material, such as indium tin oxide (ITO) or indium zinc oxide (IZO), but is not limited thereto.

At this time, a part of the plurality of conductive layers of the first pad electrode PAD1 is electrically connected to a plurality of wiring lines on the first substrate 110 to supply various signals to the plurality of wiring lines and he plurality of sub pixels SP. For example, the first conductive layer and/or the second conductive layer of the first pad electrode PAD1 is connected to the data line DL, the high potential power line VL1, and the low potential power line VL2 disposed in the active area AA to transmit signals thereto.

Referring to FIGS. 6 and 8, the plurality of metal layers and insulating layers are disposed between the plurality of first pad electrodes PAD1 and the first substrate 110.

The plurality of metal layers include a first metal layer ML1 and a second metal layer ML2 on the first metal layer ML1. The first metal layer ML1 and the second metal layer ML2 can be disposed together with the plurality of insulating layers below the first pad electrodes PAD1, for example, the buffer layer 111, the gate insulating layer 112, the first interlayer insulating layer 113, and the second interlayer insulating layer 114. Therefore, the plurality of metal layers can be insulated from the plurality of first pad electrodes PAD1. In the meantime, the plurality of metal layers may not be electrically connected to the other components, but can be electrically floated.

In the display device 100 according to the embodiment(s) of the present disclosure, the first metal layer ML1, the second metal layer ML2, and the plurality of insulating layers are disposed below the first pad electrode PAD1 to adjust a step of the first pad electrode PAD1. For example, the buffer layer 111, the gate insulating layer 112, the first metal layer ML1, the first interlayer insulating layer 113, and the second metal layer ML2 can be sequentially disposed between the first pad electrode PAD1 and the first substrate 110.

The first metal layer ML1 can be formed of the same conductive material as the gate electrode GE and the second metal layer ML2 can be formed of the same conductive material as a 1-2-th capacitor electrode C1b. However, the plurality of insulating layers, the first metal layer ML1, and the second metal layer ML2 below the first pad electrode PAD1 can be omitted depending on a design and are not limited thereto.

In the meantime, referring to FIGS. 6 and 8, an area of the plurality of metal layers on a plane view can be smaller than (e.g., in size) an area of the first pad electrode PAD1 on a plane view, but is not limited thereto.

The second substrate 120 is disposed below the first substrate 110. The second substrate 120 is a substrate which supports components disposed below the display device 100 and can be an insulating substrate. For example, the second substrate 120 can be formed of glass, resin, or the like. Further, the second substrate 120 can include polymer or plastic. The second substrate 120 can be formed of the same material as the first substrate 110. In some exemplary embodiments, the second substrate 120 can be formed of a plastic material having flexibility, rendering it flexible, bendable or rollable.

A bonding layer BDL is disposed between the first substrate 110 and the second substrate 120. The bonding layer BDL can be formed of a material which is cured by various curing methods to bond the first substrate 110 and the second substrate 120. The bonding layer BDL can be disposed only in a partial area between the first substrate 110 and the second substrate 120 or can be disposed in the entire area therebetween.

The plurality of second pad electrodes PAD2 are disposed on a rear surface of the second substrate 120. The plurality of second pad electrodes PAD2 are electrodes which transmit a signal from a driving component disposed on the rear surface of the second substrate 120 to the plurality of side lines SRL to be described below and the plurality of first pad electrodes PAD1 and the plurality of wiring lines on the first substrate 110. The plurality of second pad electrodes PAD2 are disposed in an end portion of the second substrate 120 in the non-active area NA to be electrically connected to the side line SRL which covers the end portion of the second substrate 120.

At this time, the plurality of second pad electrodes PAD2 can be also disposed so as to correspond to the plurality of pad areas. The plurality of first pad electrodes PAD1 can be disposed to correspond to the plurality of second pad electrodes PAD2, respectively, and then the first pad electrode PAD1 and the second pad electrode PAD2 which overlap each other can be electrically connected through the side line SRL.

Each of the plurality of second pad electrodes PAD2 includes a plurality of conductive layers. For example, each of the plurality of second pad electrodes PAD2 includes a fourth conductive layer PE2a, a fifth conductive layer PE2b, and a sixth conductive layer PE2c.

In an example, first, the fourth conductive layer PE2a is disposed below the second substrate 120. The fourth conductive layer PE2a can be formed of a conductive material such as copper (Cu), aluminum (Al), molybdenum (Mo), nickel (Ni), titanium (Ti), chrome (Cr), or an alloy thereof, but is not limited thereto.

The fifth conductive layer PE2b is disposed below the fourth conductive layer PE2a. The fifth conductive layer PE2b can be formed of a conductive material, such as copper (Cu), aluminum (Al), molybdenum (Mo), nickel (Ni), titanium (Ti), chrome (Cr), or an alloy thereof, but is not limited thereto.

The sixth conductive layer PE2c is disposed below the fifth conductive layer PE2b. The sixth conductive layer PE2c is formed of a conductive material, for example, a transparent conductive material, such as indium tin oxide (ITO) or indium zinc oxide (IZO), but is not limited thereto.

The second protection layer 121 (FIG. 5) is disposed in the remaining area of the second substrate 120. The second protection layer 121 can protect various wiring lines and driving components formed on the second substrate 120. The second protection layer 121 can be formed of an organic insulating material, and for example, formed of benzocyclobutene or an acrylic organic insulating material, but is not limited thereto.

In the meantime, a driving component including a plurality of flexible films and a printed circuit board can be disposed on a rear surface of the second substrate 120. The plurality of flexible films are components in which various components such as a data driver IC are disposed on a base film having a ductility to supply signals to the plurality of sub pixels SP. The printed circuit board is a component which is electrically connected to the plurality of flexible films to supply signals to the driving IC. On the printed circuit board, various components for supplying various signals to the driving IC can be disposed.

For example, the fourth conductive layer PE2a and/or the fifth conductive layer PE2b of the second pad electrode PAD2 extends to the plurality of flexible films disposed on the rear surface of the second substrate 120 to be electrically connected to the plurality of flexible films. The plurality of flexible films can supply various signals to the plurality of side lines SRL, the plurality of first pad electrodes PAD1, the plurality of wiring lines, and the plurality of sub pixels SP through the second pad electrode PAD2. Therefore, the signal from the driving component can be transmitted to the signal line SL and the plurality of sub pixels SP on the front surface of the first substrate 110 through the plurality of second pad electrodes PAD2 of the second substrate 120, the side line SRL, and the plurality of first pad electrodes PAD1 of the first substrate 110.

Next, the plurality of side lines SRL are disposed on the side surfaces of the first substrate 110 and the second substrate 120. The plurality of side lines SRL can electrically connect the plurality of first pad electrodes PAD1 formed on the top surface of the first substrate 110 and the plurality of second pad electrodes PAD2 formed on the rear surface of the second substrate 120. The plurality of side lines SRL can be disposed so as to enclose the side surface of the display device 100. Each of the plurality of side lines SRL can cover the first pad electrode PAD1 at an end portion of the first substrate 110, a side surface of the first substrate 110, a side surface of the second substrate 120, and the second pad electrode PAD2 at an end portion of the second substrate 120. For example, the plurality of side lines SRL can be formed by a pad printing method using a conductive ink, for example, including silver (Ag), copper (Cu), molybdenum (Mo), chrome (Cr), and the like.

A side insulating layer 140 which covers the plurality of side lines SRL is disposed. The side insulating layer 140 can be formed on the top surface of the first substrate 110, the side surface of the first substrate 110, the side surface of the second substrate 120, and the rear surface of the second substrate 120 to cover the side line SRL. The side insulating layer 140 can protect the plurality of side lines SRL.

At this time, when the plurality of side lines SRL are formed of a metal material, there can be an issue in that external light may be reflected from the plurality of side lines SRL or light emitted from the light emitting diode 130 may be reflected from the plurality of side lines SRL to be visibly recognized by a user. To address this issue, the side insulating layer 140 is configured to include a black material to suppress reflection of the external light. For example, the side insulating layer 140 can be formed by a pad printing method using an insulating material including a black material, for example, a black ink.

Furthermore, a seal member 150 which covers the side insulating layer 140 is disposed. The seal member 150 is disposed so as to enclose the side surface of the display device 100 to protect the display device 100 from external impacts, moisture and oxygen, or the like. For example, the seal member 150 can be formed of polyimide (PI), poly urethane, epoxy, or acryl based insulating material, but is not limited thereto.

In the meantime, referring to FIGS. 5 to 9, the optical film MF which covers the upper portions of the seal member 150, the side insulating layer 140, and the first protection layer 117 is disposed in the entire upper area of the first substrate 110. The optical film MF can be a functional film which implements a higher quality of images while protecting the display device 100. For example, the optical film MF can include an anti-scattering film, an anti-glare film, an anti-reflecting film, a low-reflecting film, an OLED transmittance controllable film, a polarizer, or the like, but is not limited thereto.

At this time, the adhering unit 118 is disposed between the seal member 150, the side insulating layer 140, and the first protection layer 117 and the optical film MF. The adhering unit 118 is formed on the front surface of the first substrate 110 to bond between the seal member 150, the side insulating layer 140, and the first protection layer 117 and the optical film MF. The adhering unit 118 can be formed of a photo curable adhesive material which is cured by light. For example, the adhering unit 118 can be formed of an acrylic material including a photoresist, but is not limited thereto.

In the meantime, in the examples of the present disclosure, the adhering unit 118 and the optical film MF can be defined as separate components, but the present disclosure is not limited thereto and the optical film MF and the adhering unit 118 can be defined as one component.

In the meantime, an edge of the seal member 150 and an edge of the optical film MF can be disposed on the same line. The optical film MF having a larger size is attached above the first substrate 110 during the manufacturing process of the display device 100 and the seal member 150 which covers the side insulating layer 140 can be formed. Thereafter, laser is irradiated on the seal member 150 and the optical film MF so as to correspond to an edge of the display device 100 to cut a part of the seal member 150 and the optical film MF. Accordingly, the size of the display device 100 is adjusted by an outer periphery cutting process of the seal member 150 and the optical film MF and the edge of the display device 100 can be formed to be flat.

When an LED or a micro LED is used as the light emitting diode (e.g., 130), the reflection plate is used in the present disclosure to upwardly reflect light emitted from the light emitting diode. At this time, as a material which configures the reflection plate, various metal materials having a high reflection can be used and silver (Ag) or a silver (Ag) alloy is the most representative material. However, silver (Ag) or a silver (Ag) alloy may be vulnerable to moisture and can cause a migration phenomenon due to a potential difference from a surrounding conductive component. Specifically, the planarization layer disposed to be adjacent to the reflection plate can be formed of an organic material so that the moisture may permeate through the planarization layer and moisture permeating through the planarization layer can accelerate the migration phenomenon. When such a migration phenomenon occurs, a short defect or limitation between the reflection plate and other conductive component disposed to be adjacent to the reflection plate can occur. Further, with such a short defect, a bright spot, a dark spot, a bright line, or a dark line can be visible.

To address these issues effectively, the display device 100 according to the embodiment of the present disclosure includes the first passivation layer 115a and the second passivation layer 115b to minimize, reduce or prevent moisture permeation through the first planarization layer 116a.

Specifically, in the present examples, the first passivation layer 115a and the second passivation layer 115b are disposed so as to be in contact with each other in the non-active area NA to seal the first planarization layer 116a. Therefore, any moisture permeation to the first planarization layer 116a which is formed of an organic material can be minimized, reduced or prevented.

To be more specific, the first passivation layer 115a and the second passivation layer 115b are disposed so as to cover ends of the first conductive layer PE1a and the second conductive layer PE1b, respectively. The first passivation layer 115a and the second passivation layer 115b are disposed to be in contact with each other in the area overlapping the plurality of first pad electrodes PAD1. The first passivation layer 115a and the second passivation layer 115b are disposed to be in contact with each other also in left and right non-active areas NA of the first substrate 110 or in two opposite non-active areas NA of the first substrate 110. Therefore, the first passivation layer 115a and the second passivation layer 115b can be disposed to have a structure which seals completely the end of the first planarization layer 116a while being in contact with each other in all the non-active areas NA. In this case, the first passivation layer 115a and the second passivation layer 115b can seal the first planarization layer 116a therein effectively. Therefore, any moisture permeation by the first planarization layer 116a which is an organic material can be minimized, reduced or prevented.

Accordingly, in the display device 100 according to the exemplary embodiment of the present disclosure, the first passivation layer 115a and the second passivation layer 115b are disposed to be in contact with each other in the non-active area NA. As a result, moisture permeation to the first planarization layer 116a which is formed of an organic material can be minimized or prevented, and the reliability of the display device 100 can be improved.

Meanwhile, in case where the reflection plate RF is provided on the first planarization layer 116a, the first passivation layer 115a and the second passivation layer 115b can also seal the reflection plate RF therein. Therefore, the reflection plate RF can be protected by the first passivation layer 115a and the second passivation layer 115b. Especially, in case the reflection plate RF is formed of silver or silver alloy, the migration phenomenon can be minimized, reduced or prevented by the present disclosure.

Therefore, the display device 100 according to the exemplary embodiments of the present disclosure is configured to minimize or prevent moisture permeation to the first planarization layer 116a which is formed of an organic material, so as to minimize or prevent short issues between the reflection plate RF and other conductive components adjacent to the reflection plate RF.

Specifically, the first passivation layer 115a and the second passivation layer 115b are disposed so as to be in contact with each other in the non-active area NA to seal the first planarization layer 116a. Therefore, any moisture permeation to the first planarization layer 116a which is formed of an organic material can be minimized or prevented. Accordingly, a short defect issue between the reflection plate RF formed of silver (Ag) or a silver (Ag) allow which can be vulnerable to the moisture and other conductive components adjacent to the reflection plate RF, for example, a source electrode SE and a drain electrode DE formed of aluminum (Al) or an aluminum (Al) alloy or other components disposed on the same layer can be minimized or addressed effectively. Accordingly, the display device 100 according to the exemplary embodiment of the present disclosure minimizes or prevents the moisture permeation to the first planarization layer 116a which is formed of an organic material, and further minimizes or prevents the short defect between the reflection plate RF and other conductive components adjacent to the reflection plate RF and thus improves the reliability of the display device 100.

The exemplary embodiments of the present disclosure can also be described as follows:

According to an aspect of the present disclosure, a display device includes a substrate including an active area in which the plurality of sub pixels are disposed and a non-active area which encloses the active area; a plurality of transistors disposed in each of the plurality of sub pixels; a first passivation layer which covers the plurality of transistors and is formed of an inorganic material; a first planarization layer which covers the first passivation layer; a second passivation layer which covers the first planarization layer and is formed of an inorganic material; an adhesive layer disposed on the second passivation layer; a plurality of light emitting diodes disposed on the adhesive layer; and a plurality of pad electrodes which are disposed in the non-active area on a top and a bottom of the substrate to transmit a signal to the plurality of sub pixels, wherein an end of the first passivation layer is covered by the first planarization layer in an area overlapping the plurality of pad electrodes, and an end of the second passivation layer is covered by the adhesive layer in the area overlapping the plurality of pad electrodes.

The plurality of pad electrodes can include a first conductive layer, a second conductive layer on the first conductive layer, and a third conductive layer on the second conductive layer.

The first passivation layer can be disposed so as to cover one end of the first conductive layer, and the second passivation layer can be disposed so as to cover one end of the second conductive layer.

The first conductive layer can be formed of the same material as source electrodes and drain electrodes of the plurality of transistors.

The display device can further comprise a reflection plate which is disposed so as to overlap the plurality of light emitting diodes between the first planarization layer and the second passivation layer.

The second conductive layer can be formed of the same material as the reflection plate.

The display device can further comprise a connection electrode which electrically connects the reflection plate and the plurality of light emitting diodes.

The third conductive layer can be formed of the same material as the connection electrode.

The first conductive layer can be formed of a material including aluminum (Al) and the second conductive layer can be formed of a material including silver (Ag).

The display device can further comprise a plurality of metal layers which is disposed between the plurality of pad electrodes and the substrate and is insulated from the plurality of pad electrodes.

The plurality of metal layers can include a first metal layer and a second metal layer on the first metal layer.

The display device can further comprise a plurality of capacitors disposed in the plurality of sub pixels.

The first metal layer can be formed of the same material as gate electrodes of the plurality of transistors and the second metal layer can be formed of the same material as capacitor electrodes of the plurality of capacitors.

An area of the plurality of metal layers on a plane view can be smaller than an area of the plurality of pad electrodes on a plane view.

The plurality of metal layers can be electrically floated.

The first passivation layer and the second passivation layer can be disposed to be in contact with each other in an area between the plurality of pad electrodes.

The second passivation layer can cover the first planarization layer in an area between the plurality of pad electrodes, and an end of the second passivation layer can be disposed on the first passivation layer in an area between the plurality of pad electrodes.

The first planarization layer extending in the non-active area can be disposed to be spaced apart from the plurality of pad electrodes between the plurality of pad electrodes, and the first passivation layer and the second passivation layer can be disposed to be in contact with each other in an area in which the plurality of pad electrodes and the first planarization layer can be spaced apart from each other.

The first passivation layer and the second passivation layer can be disposed to be in contact with each other in left and right non-active areas of the substrate.

An end of the adhesive layer in the non-active area can be disposed at the outside from an end of the first planarization layer.

The active area can further include a plurality of gate driving areas which extend from the plurality of sub pixels and can include a gate driver disposed therein.

Active layers of a plurality of transistors disposed in the plurality of sub pixels and active layers of a plurality of transistors disposed in the gate driver can be formed by oxide semiconductor, amorphous silicon, or polysilicon.

The plurality of transistors disposed in the gate driver can include active layers formed of different materials.

Although the exemplary embodiments of the present disclosure have been described in detail with reference to the accompanying drawings, the present disclosure is not limited thereto and can be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A display device, comprising:
a substrate including an active area in which a plurality of sub pixels are disposed and a non-active area adjacent to the active area;
a plurality of transistors disposed in each of the plurality of sub pixels;
a first passivation layer covering the plurality of transistors;
a first planarization layer covering the first passivation layer;
a second passivation layer covering the first planarization layer;
an adhesive layer disposed on the second passivation layer;
a plurality of light emitting diodes disposed on the adhesive layer; and
a plurality of pad electrodes disposed in the non-active area to transmit signals to the plurality of sub pixels,
wherein an end of the first passivation layer is covered by the first planarization layer in an area overlapping with the plurality of pad electrodes, and an end of the second passivation layer is covered by the adhesive layer in the area overlapping with the plurality of pad electrodes.

2. The display device according to claim 1, wherein the plurality of pad electrodes include a first conductive layer, a second conductive layer disposed on the first conductive layer, and a third conductive layer disposed on the second conductive layer,
the first passivation layer is disposed so as to cover one end of the first conductive layer, and
the second passivation layer is disposed so as to cover one end of the second conductive layer.

3. The display device according to claim 2, wherein the first conductive layer is formed of a same material as source electrodes and drain electrodes of the plurality of transistors.

4. The display device according to claim 2, further comprising:
a reflection plate disposed so as to overlap with the plurality of light emitting diodes between the first planarization layer and the second passivation layer,
wherein the second conductive layer is formed of a same material as the reflection plate.

5. The display device according to claim 4, further comprising:
a connection electrode electrically connecting the reflection plate and the plurality of light emitting diodes,
wherein the third conductive layer is formed of a same material as the connection electrode.

6. The display device according to claim 2, wherein the first conductive layer is formed of a material including aluminum (Al), and the second conductive layer is formed of a material including silver (Ag).

7. The display device according to claim 1, further comprising:
a plurality of metal layers disposed between the plurality of pad electrodes and the substrate, and insulated from the plurality of pad electrodes,
wherein the plurality of metal layers include a first metal layer and a second metal layer disposed on the first metal layer.

8. The display device according to claim 7, further comprising:
a plurality of capacitors disposed in the plurality of sub pixels,
wherein the first metal layer is formed of a same material as gate electrodes of the plurality of transistors, and the second metal layer is formed of a same material as capacitor electrodes of the plurality of capacitors.

9. The display device according to claim 7, wherein an area of the plurality of metal layers on a plane view is smaller than an area of the plurality of pad electrodes on a plane view.

10. The display device according to claim 7, wherein the plurality of metal layers are electrically floated.

11. The display device according to claim 1, wherein the first passivation layer and the second passivation layer contact with each other in an area of the non-active area between the plurality of pad electrodes.

12. The display device according to claim 11, wherein the second passivation layer covers the first planarization layer in an area between the plurality of pad electrodes, and
an end of the second passivation layer is disposed on the first passivation layer in an area between the plurality of pad electrodes.

13. The display device according to claim 11, wherein the first planarization layer extending in the non-active area is disposed to be spaced apart from the plurality of pad electrodes between the plurality of pad electrodes, and
the first passivation layer and the second passivation layer contact with each other in an area in which the plurality of pad electrodes and the first planarization layer are spaced apart from each other.

14. The display device according to claim 1, wherein the first passivation layer and the second passivation layer are disposed to be in contact with each other in left and right non-active areas of the substrate, or in two opposite non-active areas of the substrate.

15. The display device according to claim 1, wherein an end of the adhesive layer in the non-active area is disposed outside from an end of the first planarization layer.

16. The display device according to claim 1, wherein the active area further includes a plurality of gate driving areas extending from the plurality of sub pixels and having a gate driver disposed therein.

17. The display device according to claim 16, wherein active layers of the plurality of transistors disposed in the plurality of sub pixels and active layers of a plurality of transistors disposed in the gate driver include oxide semiconductor, amorphous silicon, or polysilicon.

18. The display device according to claim 17, wherein the plurality of transistors disposed in the gate driver include active layers formed of different materials.

19. The display device according to claim 1, wherein at least one of the first and second passivation layers is formed of an inorganic material.

20. A display device, comprising:
a substrate including an active area and a non-active area adjacent to the active area;
a plurality of sub pixels disposed in the active area and each including a plurality of transistors;
a first passivation layer covering the plurality of transistors;
a planarization layer covering the first passivation layer;
a second passivation layer covering the planarization layer;
an adhesive layer disposed on the second passivation layer; and
a plurality of light emitting diodes disposed on the adhesive layer,
wherein the first passivation layer and the second passivation contact with each other in the non-active area, so as to seal an end portion of the planarization layer.

21. The display device according to claim 20, further comprising a reflection plate disposed in each of the plurality of sub pixels on the planarization layer.

22. The display device according to claim 21, wherein the reflection plate is formed of Ag or Ag alloy.

23. The display device according to claim 21, wherein the reflection plate has a shape corresponding to the plurality of sub pixels covered by the reflection plate.

24. The display device according to claim 21, wherein the reflection plate electrically connects one of the plurality of light emitting diodes to a pixel circuit for driving the one of the plurality of light emitting diodes.

25. The display device according to claim 20, further comprising:
another planarization layer disposed on the adhesive layer and surrounding the plurality of light emitting diodes,
wherein the another planarization layer includes a step for minimizing electrical shorts.

26. The display device according to claim 20, wherein the first and second passivation layers are formed of an inorganic material, and the planarization layer is formed of an organic material.
